(19) United States
(12) Patent Application Publication
(10) Pub. No.: US 2011/0227215 A1
(43) Pub. Date: Sep. 22, 2011

(54) ELECTRONIC DEVICE, PACKAGE INCLUDING THE SAME AND METHOD OF FABRICATING THE PACKAGE

(76) Inventors: Boseong KIM, Seoul (KR); Jinho Kim, Yongin-si (KR)

(21) Appl. No.: 13/051,023

(22) Filed: Mar. 18, 2011

(30) Foreign Application Priority Data
Mar. 19, 2010 (KR) 10-2010-0024716

(51) Int. Cl. H01L 23/48; H01L 21/28

(52) U.S. Cl. 257/734; 438/597; 257/E23.01; 257/E21.158

(57) ABSTRACT

An electronic device, a package including the same, and a method of fabricating the package, the electronic device including a substrate having an operation structure therein; a first passivation layer on a first side of the substrate; and first conductive patterns on a second side of the substrate, the first conductive patterns being electrically connected to the operation structure, wherein the first passivation layer has a higher flexibility than the substrate when the substrate and the first passivation layer are bent.

### BACKGROUND

1. Field

Embodiments relate to an electronic device, a package including the same, and a method of fabricating the package.

2. Description of the Related Art

With the development of electric/electronic technology, research is being conducted on packages having electric/electronic devices adhered to garments. Packages having a high flexibility and a high moisture resistance may be desirable for implementation of electric/electronic devices for garments.

### SUMMARY

Embodiments are directed to an electronic device, a package including the same, and a method of fabricating the package.

The embodiments may be realized by providing an electronic device including a substrate having an operation structure therein; a first passivation layer on a first side of the substrate; and first conductive patterns on a second side of the substrate, the first conductive patterns being electrically connected to the operation structure, wherein the first passivation layer has a higher flexibility than the substrate when the substrate and the first passivation layer are bent.

The first passivation layer may be thicker than the substrate.

The first passivation layer may have a thickness of about 50 μm to about 250 μm, and the substrate may have a thickness of about 5 μm to about 30 μm.

The first passivation layer may include a polyimide polymer.

The electronic device may further include a second passivation layer on the second side of the substrate, the second passivation layer filling a space between the first conductive patterns.

The second passivation layer may include a polymer resin.

The substrate and the first and second passivation layers may have a total thickness of about 200 μm to about 500 μm.

The operation structure may include a memory chip, a non-memory chip, a solar cell, or a display device.

The operation structure may include a solar cell or a display device, the first passivation layer may be formed of a transparent material, and the operation structure may be adjacent to the first side of the substrate to which the first passivation layer is adhered.

The electronic device may further include a via contact at the substrate, the via contact electrically connecting the operation structure and the first conductive patterns.

The operation structure may include a memory chip or a non-memory chip, and the operation structure may be adjacent to the second side of the substrate where the first conductive patterns are formed.

The operation structure and the first conductive patterns may be directly electrically connected to each other.

The embodiments may also be realized by providing a package including a semiconductor device, the semiconductor device including a first substrate having an operation structure therein, a first passivation layer on a first side of the substrate, and first conductive patterns on a second side of the substrate, the first conductive patterns being electrically connected to the operation structure; and a second substrate, the second substrate including second conductive patterns electrically connected to the first conductive patterns, wherein the first passivation layer has a higher flexibility than the first substrate when the substrate and the first passivation layer are bent.

The second substrate may include a fabric.

The first passivation layer may include a material having a moisture resistance higher than a moisture resistance of the second substrate.

The embodiments may also be realized by providing a method of fabricating a package, the method including preparing a substrate such that the substrate includes an operation structure; forming a first passivation layer on a first side of the substrate; forming first conductive patterns and a second passivation layer on a second side of the substrate; preparing a circuit substrate such that the circuit substrate includes second conductive patterns; and electrically connecting the first and second conductive patterns, wherein the first passivation layer has a higher flexibility than the substrate when the substrate and the first passivation layer are bent.

Preparing the substrate may include preparing an initial substrate such that the initial substrate has the operation structure therein; forming the first passivation layer on the first side of the initial substrate; and polishing the second side of the initial substrate such that the substrate is thinner than the first passivation layer.

The second passivation layer may be formed of a semi-cured material, and electrically connecting the first and second conductive patterns may include curing the second passivation layer.

Electrically connecting the first and second conductive patterns may include performing a heating process at a melting temperature of the conductive material of the first conductive patterns, and curing the second passivation layer may occur during the heating process.

The method may further include forming a via contact between the operation structure and the first conductive patterns, wherein the operation structure includes a solar cell or a display device, and preparing the initial substrate includes forming the operation structure adjacent to the first side of the substrate.

### BRIEF DESCRIPTION OF THE DRAWINGS

The embodiments will become more apparent to those of ordinary skill in the art by describing in detail exemplary embodiments with reference to the attached drawings, in which:

FIGS. 1A to 1H illustrate cross-sectional views of stages in a method of fabricating a package according to an embodiment;

FIGS. 2A and 2B illustrate cross-sectional views of stages in a method of fabricating a package according to another exemplary embodiment of the inventive concept;

FIGS. 3A and 3B respectively illustrate a graph and a table showing a radius of curvature according to a thickness of a substrate; and

FIG. 4 illustrates a schematic diagram of a garment with a package according to an embodiment.

### DETAILED DESCRIPTION

Korean Patent Application No. 10-2010-0024716, filed on Mar. 19, 2010, in the Korean Intellectual Property Office, and entitled: “Electronic Device, Package Including the Same and Method of Fabricating the Package,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

The embodiments are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate specific shapes of device regions. Thus, these should not be construed as limiting the scope of the embodiments. Although terms like a first, a second, and a third may be used to describe various elements in various embodiments, the elements are not limited by these terms. These terms are used only to distinguish one element from another element. An embodiment described and exemplified herein includes a complementary embodiment thereof.

In the following description, the technical terms are used only to describe specific exemplary embodiments while not limiting the thereof. The terms of a singular form may include a plural form unless otherwise specified. The meaning of “include”, “comprise”, “including” or “comprising” specifies a property, a region, a fixed number, a step, a process, an element and/or a component but does not exclude other properties, regions, fixed numbers, steps, processes, elements and/or components.

### EMBODIMENT 1

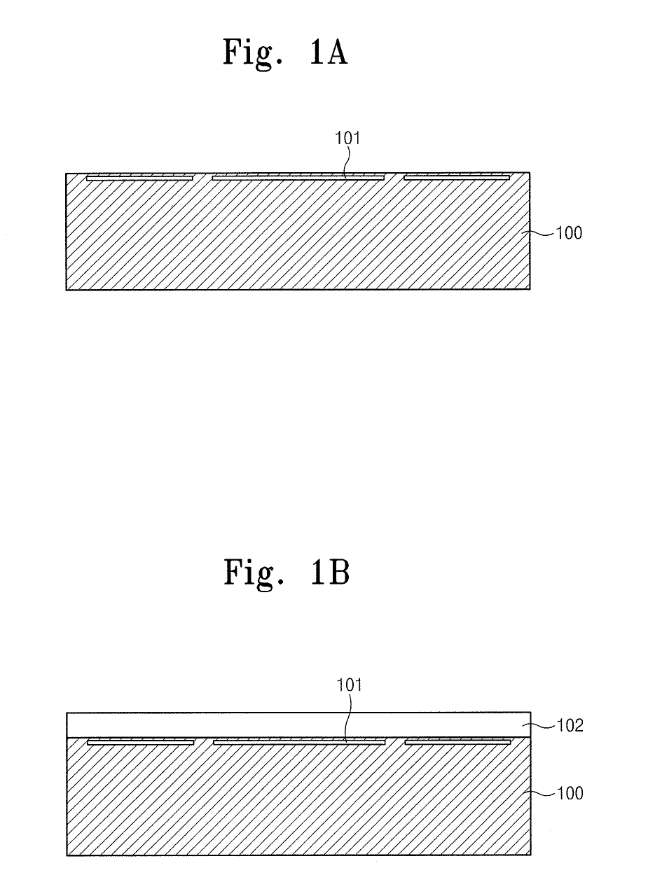

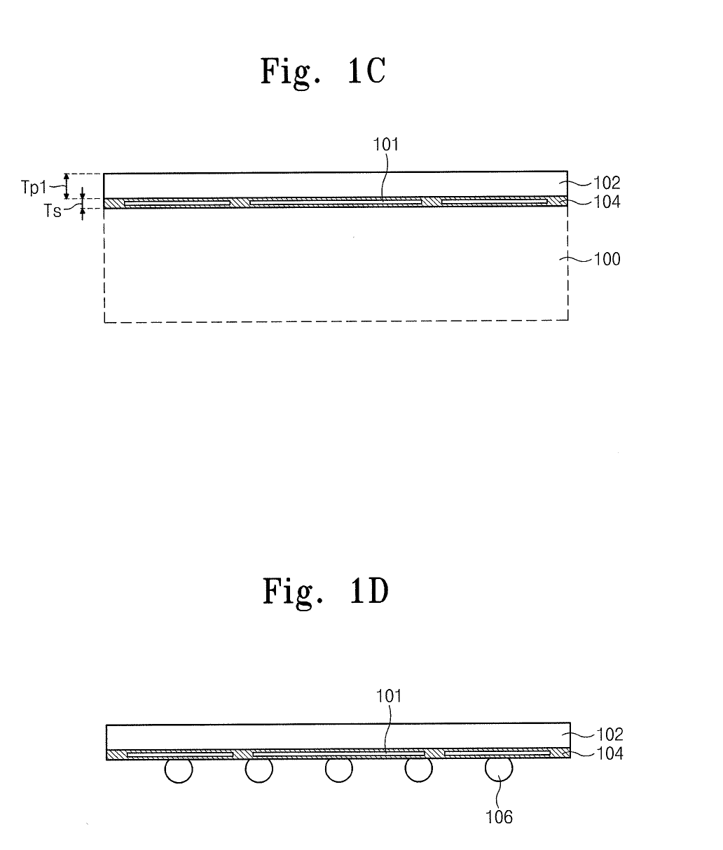

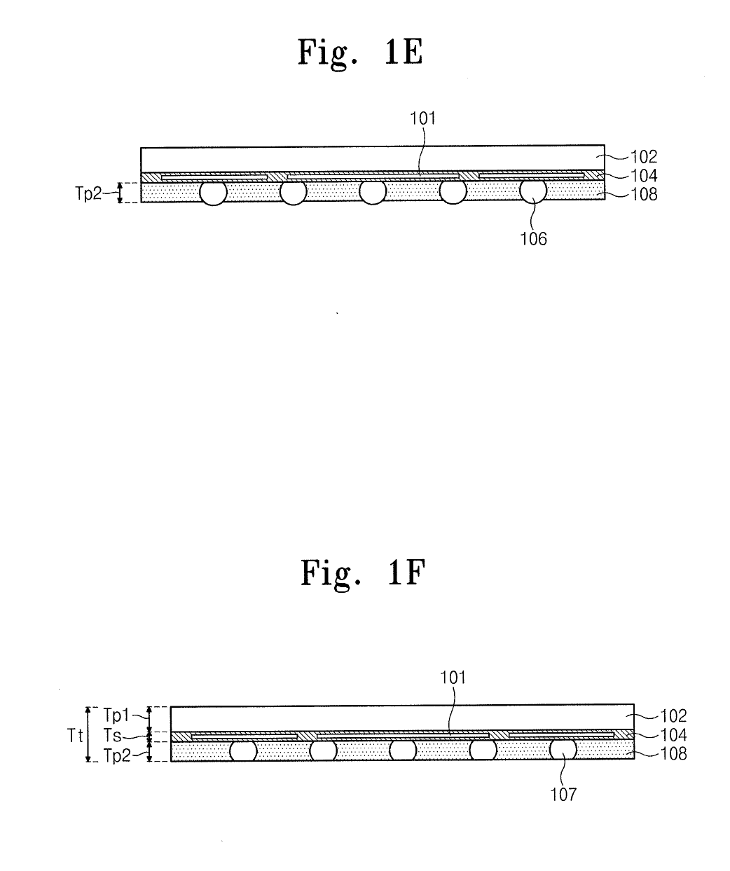

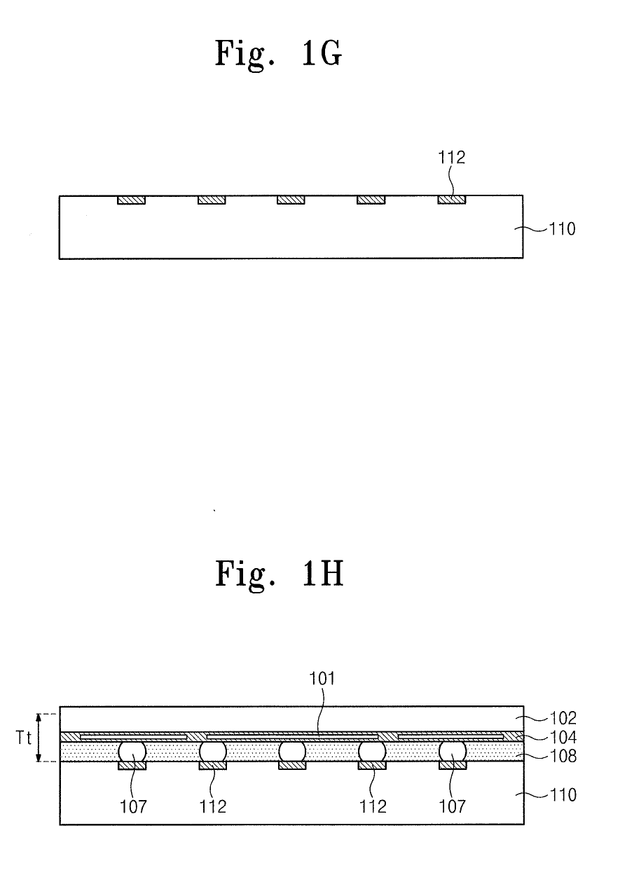

FIGS. 1A to 1H illustrate cross-sectional views of stages in a method of fabricating a package according to an embodiment.

Referring to FIG. 1A, an initial substrate 100 including an operation structure 101 may be prepared.

The initial substrate 100 may include, e.g., silicon or ceramic. Typically, if the initial substrate 100 (including silicon or ceramic) is bent by an external force, the initial substrate 100 may be broken due to its low curvature or flexibility.

However, the flexibility of the initial substrate 100 may vary according to a thickness of the initial substrate 100. For example, the flexibility of the initial substrate 100 may increase with a decrease in the thickness of the initial substrate 100. Thus, as the thickness of the initial substrate 100 decreases, the initial substrate 100 may be bent more easily without being broken.

The operation structure 101 may be formed in the initial substrate 100. The operation structure 101 may include, e.g., a memory chip, a non-memory chip, a solar cell, a display device, or a combination thereof.

Referring to FIG. 1B, a first passivation layer 102 may be formed on a first side of the initial substrate 100.

The first passivation layer 102 may include, e.g., an organic material such as a polymer. In an implementation, the first passivation layer 102 may include, e.g., a polyimide. A polyimide is a polymer with an imide chain and may be very chemically stable. Thus, the first passivation layer 102 including a polyimide may exhibit, e.g., a high heat resistance, a high chemical resistance, a high wear resistance, and a high weather resistance. Also, the first passivation layer 102 may be stable in a humid or moist environment.

The first passivation layer 102 may be formed to a thickness of about 50 μm to about 250 μm. For example, the first passivation layer 102 may be formed to a thickness sufficient to prevent breaking of a thin substrate formed in a subsequent process.

In an implementation, if the operation structure 101 includes a solar cell or a display device, the first passivation layer 102 may be transparent. Thus, the operation structure 101 may be formed adjacent to the first side of the initial substrate 100 (where the first passivation layer 102 is formed).

In another implementation, if the operation structure 101 includes a memory chip or a non-memory chip, it may be irrelevant whether the first passivation layer 102 is transparent and where the operation structure 101 is located. For example, the operation structure 101 may be adjacent to first conductive patterns 107 (see FIG. 1F) formed in a subsequent process.

Referring to FIG. 1C, another or second side of the initial substrate 100 may be thinned, e.g., by polishing, to form a substrate 104. The second side of the initial substrate 100 may be polished through, e.g., a chemical mechanical polishing process or an etch-back process.

The substrate 104 (formed by polishing the initial substrate 100) may have a substantially smaller thickness Ts than the initial substrate 100. For example, the substrate 104 may have a thickness of about 5 μm to about 30 μm.

The substrate 104 (which may be thinner than the initial substrate 100) may have a substantially higher flexibility than the initial substrate 100. The flexibility of the substrate 104 may increase with a decrease in the thickness of the substrate 104. Accordingly, the substrate 104 may be bent more easily as the thickness of the substrate 104 decreases.

However, if the substrate 104 has a small thickness, it may be easily broken by an external force or shock. Accordingly, the first passivation layer 102 may be included on the first side of the substrate 104 to prevent the substrate 104 from being broken by an external force or shock.

Also, the first passivation layer 102 may have a substantially higher flexibility than the substrate 104. For example, if the substrate 104 has a thickness of about 5 μm to about 30 μm and the first passivation layer 102 has a thickness of about 50 μm to about 250 μm, the first passivation layer 102 may have a substantially higher flexibility than the substrate 104, while also having a greater thickness Tp1 than the substrate 104. Thus, a decrease in the flexibility of a package may be prevented, even when the first passivation layer 102 (which may be thicker than the substrate 104) is adhered to the substrate 104.

Polishing by-products may be generated during the polishing of the initial substrate 100. Adhesion of the polishing by-products to the first side of the substrate 104 may be prevented by polishing the second side of the initial substrate 100 after forming the first passivation layer 102 on the first side of the initial substrate 100.

Referring to FIG. 1D, preliminary first conductive patterns 106 may be formed on the second side of the substrate 104.

The preliminary first conductive patterns 106 may include, e.g., solder balls. For example, the preliminary first conductive patterns 106 may be formed on the second side of the substrate 104 (opposite to the first side of the substrate 104) where the first passivation layer 102 is formed.

The preliminary first conductive patterns 106 may be electrically connected to the operation structure 101 in the substrate 104. In an implementation, if the operation structure 101 includes a solar cell or a display device, the operation structure 101 may be adjacent to the first side of the substrate 104 and the preliminary first conductive patterns 106 may be adjacent to the second side of the substrate 104, for efficient operation. The operation structure 101 may be electrically connected to the preliminary first conductive patterns 106 through a via contact (not illustrated).

In another implementation, if the operation structure 101 includes a memory chip or a non-memory chip, the operation structure 101 may be adjacent to the preliminary first conductive patterns 106. Accordingly, the operation structure 101 and the preliminary first conductive patterns 106 may be adjacent to the same, e.g., second, side of the substrate 104. Thus, a connection pattern, e.g., a via contact, may be omitted.

Referring to FIG. 1E, a second passivation layer 108 may be formed on the second side of the substrate 104 to fill a space between the preliminary first conductive patterns 106.

The second passivation layer 108 may include a material that is stable in a humid or moist environment. In an implementation, the second passivation layer 108 may include, e.g., a resin. Also, the second passivation layer 108 may include a semi-cured material. The second passivation layer 108 may be fully cured in a subsequent process. This will be described in greater detail below.

The second passivation layer 108 may be formed to a thickness Tp2 sufficient to prevent breaking of the substrate 104 (in combination with the first passivation layer 102). For example, the second passivation layer 108 may be formed to a thickness of about 50 μm to about 250 μm.

The second passivation layer 108 may have a substantially higher flexibility than the substrate 104. For example, if the substrate 104 has a thickness of about 5 μm to about 30 μm and the second passivation layer 108 has a thickness of about 50 μm to about 250 μm, the second passivation layer 108 may have a substantially higher flexibility than the substrate 104, while still having a substantially greater thickness than the substrate 104. Thus, a decrease in the flexibility of a package may be prevented, even when the second passivation layer 108 (which may be thicker than the substrate 104) is adhered to the substrate 104.

The second passivation layer 108 may be formed to a lower level than the preliminary first conductive patterns 106, e.g., the thickness Tp2 of the second passivation layer 108 may be less than a thickness of the preliminary first conductive patterns 106. Thus, portions of the preliminary first conductive patterns 106 may be exposed by the second passivation layer 108.

Referring to FIG. 1F, the preliminary first conductive patterns 106 may be etched to form first conductive patterns 107.

For example, the preliminary first conductive patterns 106 exposed by the second passivation layer 108 may be etched. The preliminary first conductive patterns 106 may be etched through, e.g., a chemical physical polishing process, an etch-back process, and/or a wet etching process.

As a result of the etching process, bottoms of the first conductive patterns 107 may have substantially the same level as, e.g., may be substantially coplanar with, a bottom of the second passivation layer 108.

The substrate 104, the first conductive pattern 107, and the first and second passivation layers 102 and 108 may have a total thickness Tt of about 300 μm to about 500 μm.

Referring to FIG. 1G, a circuit substrate 110 having second conductive patterns 112 formed therein may be prepared.

The circuit substrate 110 may include, e.g., a pattern providing a path for an electrical signal for data exchange with the substrate 104, a pattern for grounding or transmitting power to the substrate 104, and/or a pattern for contacting an external terminal.

In an implementation, the circuit substrate 110 may be formed of a fabric. In another implementation, the circuit substrate 110 may be a flexible printed circuit board or a printed circuit board (PCB) having a copper-foil circuit pattern formed on one side or both sides of a core formed of reinforced fiberglass or epoxy resin.

The second conductive patterns 112 may be formed at one side of the circuit substrate 110. The second conductive patterns 112 may include, e.g., copper, aluminum, nickel, and/or gold.

Referring to FIG. 1H, the first conductive patterns 107 and the second conductive patterns 112 may be electrically connected to each other.

In an implementation, the first and second conductive patterns 107 and 112 may be joined together. Then, the first and second conductive patterns 107 and 112 may be heated at high temperature. The heating process may be performed at a melting temperature of the conductive material of the first conductive patterns 107. For example, if the first conductive patterns 107 include solder balls, the heating process may be performed at the melting temperature of the solder balls. The molten first conductive patterns 107 may ten be electrically connected to the second conductive patterns 112.

In the heating process for electrically connecting the first and second conductive patterns 107 and 112, the second passivation layer 108 may change from a semi-cured state to a cured state. In a semi-cured state, atoms in a material may have an unstable and irregular structure. The semi-cured material may change into a cured state that has a stable and regular atom structure at a high-temperature.

Accordingly, fabrication of a package including the substrate 104, the first and second passivation layers 102 and 108, the first and second conductive patterns 107 and 112, and the circuit substrate 110 may be completed. The first and second passivation layers 102 and 108 may be formed at both sides of the thin substrate 104, thereby facilitating fabrication of a package that exhibits high flexibility and high moisture resistance.

### EMBODIMENT 2

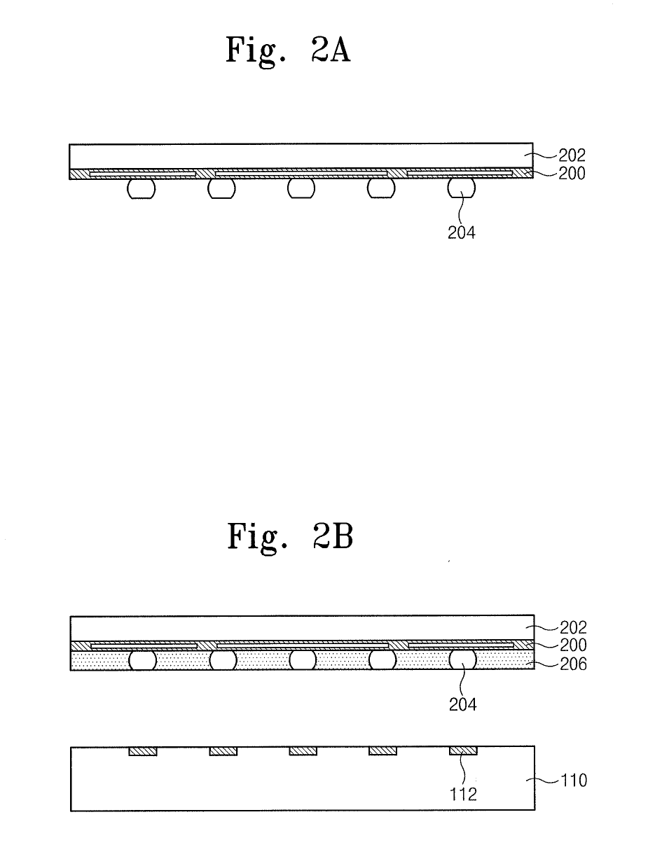

FIGS. 2A and 2B illustrate cross-sectional views of stages in a method of fabricating a package according to another embodiment.

Referring to FIG. 2A, preliminary first conductive patterns (not illustrated) may be formed on a second side of a substrate 200 having a first passivation layer 202 on a first side thereof. The first side and the second side may be opposite to each other. In an implementation, preparing the substrate 200 having a first passivation layer 202 on the first side thereof may be substantially the same as that described with reference to FIGS. 1A to 1D of Embodiment 1. Thus, a repeated description thereof will be omitted.

The preliminary first conductive patterns may be partially etched to form first conductive patterns 204.

Referring to FIG. 2B, a second passivation layer 206 may be formed at the second side of the substrate 200 where the first conductive patterns 204 are formed. A bottom of the second passivation layer 206 may have the same level as, e.g., may be substantially coplanar with, bottoms of the first conductive patterns 204.

A circuit substrate 110 having second conductive patterns 112 formed therein may be prepared. The first and second conductive patterns 204 and 112 may be electrically connected to complete fabrication of a package. Preparing the circuit substrate 110 having the second conductive patterns 112 formed therein, and electrically connecting the first and second conductive patterns 204 and 112 may be substantially the same as those described with reference to FIGS. 1G and 1H of Embodiment 1. Thus, a repeated description thereof will be omitted.

Exemplary Experiment

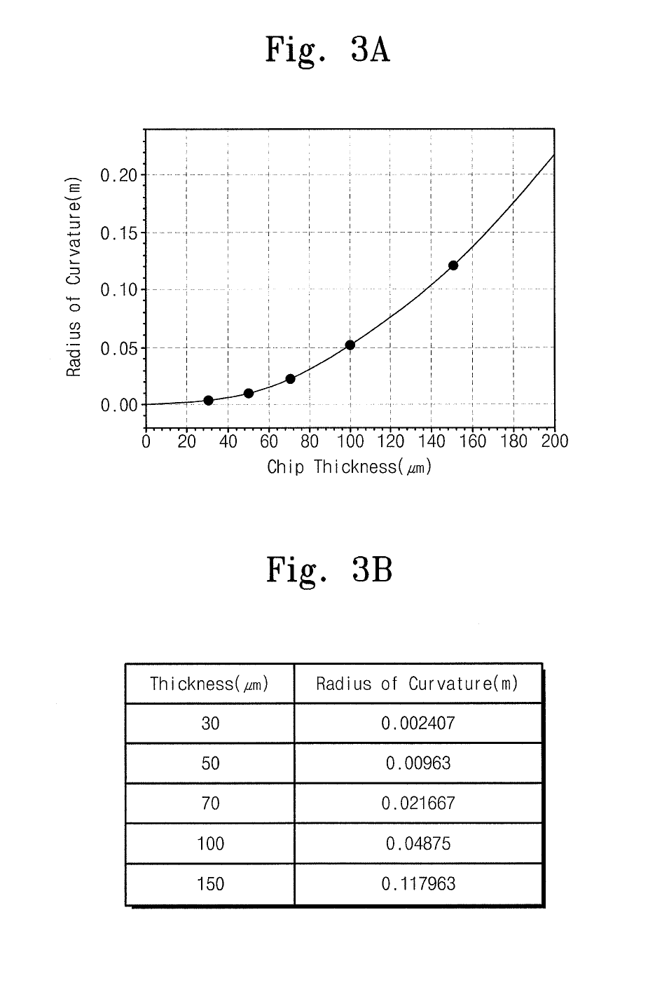

FIGS. 3A and 3B respectively illustrate a graph and a table showing radius of curvature according to a thickness of a substrate.

Referring to FIGS. 3A and 3B, a substrate 104 including silicon was prepared. Also, through the polishing process illustrated in FIG. 1C, the thickness Ts of the substrate 104 was decreased from about 150 μm to about 30 μm. A radius of curvature of the substrate 104 at each thickness Ts was observed while decreasing the thickness Ts.

Herein, the radius of curvature may refer to a value representing a degree of curvature of a curve or a curved surface at a given point. The radius of curvature of a plane surface is infinite; and the radius of curvature of a sphere or a circle is equal to the radius of the sphere or the circle. Accordingly, a decrease in the radius of curvature represents that the substrate 104 may be bent more easily, e.g., may be more flexible.

As may be seen in the graph of FIG. 3A, if the thickness Ts of the substrate 104 is smaller than about 30 μm, the radius of curvature converges to about 0. If the radius of curvature is 0, it means that the substrate 104 was broken when bent.

According to the embodiments, when the initial substrate 100 is polished to form the substrate 104, the substrate 104 may have a thickness Ts of about 5 μm to about 30 μm. If the thickness Ts decreases to 30 μm or less, the substrate 104 (without the first and/or second passivation layers 102 and 108 thereon) may be broken without being bent. Thus, in the embodiments, the first and second passivation layers 102 and 108 may be formed on the substrate 104 to prevent breaking of the substrate 104.

Exemplary Application

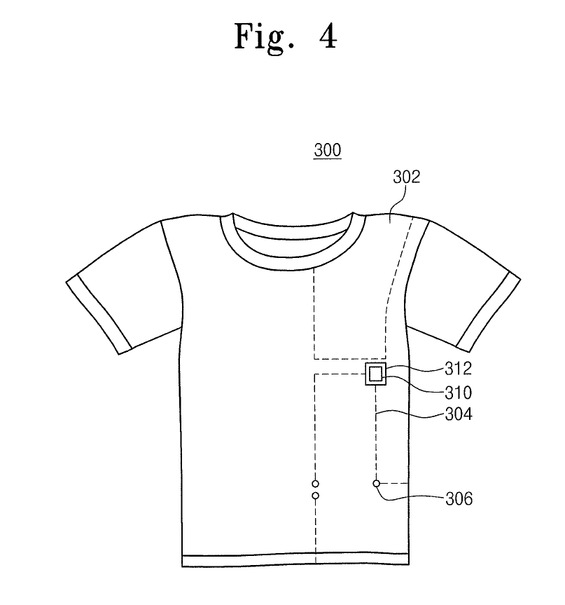

FIG. 4 illustrates a schematic diagram of a garment with a package according to an embodiment.

Referring to FIG. 4, a garment 300 may include a fabric 302, a package 310/312 according to an embodiment, an external device 306, and a circuit. The fabric 302 may include, e.g., an artificial fabric or a natural fabric. According to an embodiment, a second substrate 312 of the package 310/312 may be a fabric-type circuit substrate. The fabric-type circuit substrate 312 may be disposed in the fabric 302. For example, the fabric-type circuit substrate 312 may be woven in the garment 300 such that the fabric-type circuit substrate 312 is connected to a conductive fiber track 304. The conductive fiber track 304 may provide a signal from one package to, e.g., another package, the external device 306, or the circuit. Herein, a reference numeral ‘310’ may denote a structure that includes a first substrate, a first passivation layer, and a second passivation layer.

In this exemplary application, an operation device of the package 310/312 may include, e.g., a memory chip, a non-memory chip, a solar cell, and/or a display device. If the operation device includes a display device, it may display a logo or a message on a surface of the garment 300.

The package 310/312 according to the embodiments may have the first and second passivation layers (which may exhibit high flexibility and high moisture resistance) at both sides of the substrate. Thus, it may be possible to implement the package 310/312 exhibiting high flexibility and high moisture resistance. Accordingly, as may be seen from this exemplary application, the package 310/312 according to the embodiments may be suitably applicable to flexible materials such as garments.

The embodiments provide an electronic device that has a high flexibility and a high moisture resistance. Accordingly, embodiments relate to an electronic device applicable to flexible substrates such as garments.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An electronic device, comprising:
a substrate having an operation structure therein;
a first passivation layer on a first side of the substrate; and
first conductive patterns on a second side of the substrate, the first conductive patterns being electrically connected to the operation structure,
wherein the first passivation layer has a higher flexibility than the substrate when the substrate and the first passivation layer are bent.

2. The electronic device as claimed in claim 1, wherein the first passivation layer is thicker than the substrate.

3. The electronic device as claimed in claim 2, wherein:
the first passivation layer has a thickness of about 50 μm to about 250 μm, and
the substrate has a thickness of about 5 μm to about 30 μm.

4. The electronic device as claimed in claim 1, wherein the first passivation layer includes a polyimide polymer.

5. The electronic device as claimed in claim 1, further comprising a second passivation layer on the second side of the substrate, the second passivation layer filling a space between the first conductive patterns.

6. The electronic device as claimed in claim 5, wherein the second passivation layer includes a polymer resin.

7. The electronic device as claimed in claim 5, wherein the substrate and the first and second passivation layers have a total thickness of about 200 μm to about 500 μm.

8. The electronic device as claimed in claim 1, wherein the operation structure includes a memory chip, a non-memory chip, a solar cell, or a display device.

9. The electronic device as claimed in claim 8, wherein:
the operation structure includes a solar cell or a display device,
the first passivation layer is formed of a transparent material, and
the operation structure is adjacent to the first side of the substrate to which the first passivation layer is adhered.

10. The electronic device as claimed in claim 9, further comprising a via contact at the substrate, the via contact electrically connecting the operation structure and the first conductive patterns.

11. The electronic device as claimed in claim 8, wherein:
the operation structure includes a memory chip or a non-memory chip, and
the operation structure is adjacent to the second side of the substrate where the first conductive patterns are formed.

12. The electronic device as claimed in claim 11, wherein the operation structure and the first conductive patterns are directly electrically connected to each other.

13. A package, comprising:
a semiconductor device, the semiconductor device including:
a first substrate having an operation structure therein,
a first passivation layer on a first side of the substrate, and
first conductive patterns on a second side of the substrate, the first conductive patterns being electrically connected to the operation structure; and
a second substrate, the second substrate including second conductive patterns electrically connected to the first conductive patterns,
wherein the first passivation layer has a higher flexibility than the first substrate when the substrate and the first passivation layer are bent.

14. The package as claimed in claim 13, wherein the second substrate includes a fabric.

15. The package as claimed in claim 14, wherein the first passivation layer includes a material having a moisture resistance higher than a moisture resistance of the second substrate.

16. A method of fabricating a package, the method comprising:
preparing a substrate such that the substrate includes an operation structure;
forming a first passivation layer on a first side of the substrate;
forming first conductive patterns and a second passivation layer on a second side of the substrate;
preparing a circuit substrate such that the circuit substrate includes second conductive patterns; and
electrically connecting the first and second conductive patterns,
wherein the first passivation layer has a higher flexibility than the substrate when the substrate and the first passivation layer are bent.

17. The method as claimed in claim 16, wherein preparing the substrate includes:
preparing an initial substrate such that the initial substrate has the operation structure therein;
forming the first passivation layer on the first side of the initial substrate; and
polishing the second side of the initial substrate such that the substrate is thinner than the first passivation layer.

18. The method as claimed in claim 17, wherein:
the second passivation layer is formed of a semi-cured material, and
electrically connecting the first and second conductive patterns includes curing the second passivation layer.

19. The method as claimed in claim 18, wherein:
electrically connecting the first and second conductive patterns includes performing a heating process at a melting temperature of the conductive material of the first conductive patterns, and
curing the second passivation layer occurs during the heating process.

20. The method as claimed in claim 17, further comprising forming a via contact between the operation structure and the first conductive patterns, wherein:
the operation structure includes a solar cell or a display device, and
preparing the initial substrate includes forming the operation structure adjacent to the first side of the substrate.
